(19) United States
(12) Patent Application Publication
(10) Pub. No.: US 2009/0141534 A1
(43) Pub. Date: Jun. 4, 2009

(54) DETECTION APPARATUS AND METHOD FOR SEQUENTIALLY PROGRAMMING MEMORY

(75) Inventors: Chia-Chiuan CHANG, Miaoli County (TW); Jui-Lung Chen, Hsinchu City (TW); Yi-Hsun Chung, Miaoli County (TW); Wei-Shung Chen, Hsinchu County (TW)

Correspondence Address: QUINTERO LAW OFFICE, PC, 2210 MAIN STREET, SUITE 200, SANTA MONICA, CA, 90405, US

(73) Assignee: VANGUARD INTERNATIONAL SEMICONDUCTOR CORPORATION, Hsinchu (TW)

(21) Appl. No.: 12/191,129

(22) Filed: Aug. 13, 2008

(30) Foreign Application Priority Data
Nov. 30, 2007 (TW) TW96145682

(51) Int. Cl. G11C 17/16; G11C 7/00; G11C 8/00

(52) U.S. Cl. 365/96; 365/239; 365/189.011; 365/225.7

(57) ABSTRACT

A detection apparatus for sequentially programming a memory is provided. The detection apparatus comprises a current sensor and a programming controller. The current sensor is coupled to a programming source and a memory cell. The current sensor detects change of a programming current between the programming source and the memory cell and generates a control signal according to the detection result. The programming controller is coupled to the current sensor. The programming controller receives the control signal and generates a programming state signal.

### CROSS REFERENCE TO RELATED APPLICATIONS

This application claims the benefit of Taiwan application Serial No. 96145682 filed Nov. 30, 2007, the subject matter of which is incorporated herein by reference.

### BACKGROUND OF THE INVENTION

1. Field of the Invention

The invention relates to a memory, and more particularly to a detection apparatus for sequentially programming a memory.

2. Description of the Related Art

Fuse memory cell circuits are one type of typical one-time programmable (OTP) memory. In general, a conventional fuse memory cell circuit requires a plurality of programming pads for programming, which occupies a large area, thus increasing costs. In order to reduce occupied area of a fuse memory cell circuit, the amount of programming pads must decrease. Thus, it is desired to sequentially program a memory with a single programming pad.

Assuming that a memory is programmed sequentially, during the programming procedure, some idle resources (such as data transmission lines) can be used for other works, thus enhancing efficiency of the memory.

### BRIEF SUMMARY OF THE INVENTION

An exemplary embodiment of a detection apparatus for sequentially programming a memory is provided, comprising a current sensor and a programming controller. The current sensor is coupled to a programming source and a memory cell. The current sensor detects change of a programming current between the programming source and the memory cell and generates a control signal according to the detection result. The programming controller is coupled to the current sensor. The programming controller receives the control signal and generates a programming state signal.

Another exemplary embodiment of a detection apparatus for sequentially programming a memory is provided, comprising a voltage sensor and a programming controller. The voltage sensor is coupled to a programming source through a memory cell. The voltage sensor detects an output voltage of the memory cell and generates a control signal according to the detection result. The programming controller is coupled to the voltage sensor. The programming controller receives the control signal and generates a programming state signal.

An exemplary embodiment of a detection method for sequentially programming a memory is provided, comprising detecting change of a programming current between a programming source and a memory cell, generating a control signal according to the detection signal, and generating a programming state signal according to the control signal.

Another exemplary embodiment of a detection method for sequentially programming a memory is provided, comprising detecting an output voltage of a memory cell, generating a control signal according to the detection signal, and generating a programming state signal according to the control signal.

Another exemplary embodiment of a detection apparatus for sequentially programming a memory is provided. According to the detection apparatus, a current sensor or voltage sensor is used to detect a programming state of a memory cell and determine whether a programming procedure for the next memory is performed. In this sequential programming mode, only one programming pad is required. Compared with a conventional memory with a plurality of programming pads, the memory programmed sequentially according to the invention saves area and costs. Moreover, during the procedure for sequentially programming memory, some idle resources (such as data transmission lines) can be used for other works, thus enhancing efficiency of the memory.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1A shows an exemplary embodiment of a detection apparatus for sequentially programming a memory;

FIG. 1B shows the current sensor in FIG. 1A;

FIG. 2A shows another exemplary embodiment of a detection apparatus for sequentially programming a memory;

FIG. 2B shows the voltage sensor in FIG. 2A;

FIG. 3 is a flow chart of an exemplary embodiment of a detection method for sequentially programming a memory; and

FIG. 4 is a flow chart of another exemplary embodiment of a detection method for sequentially programming a memory.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

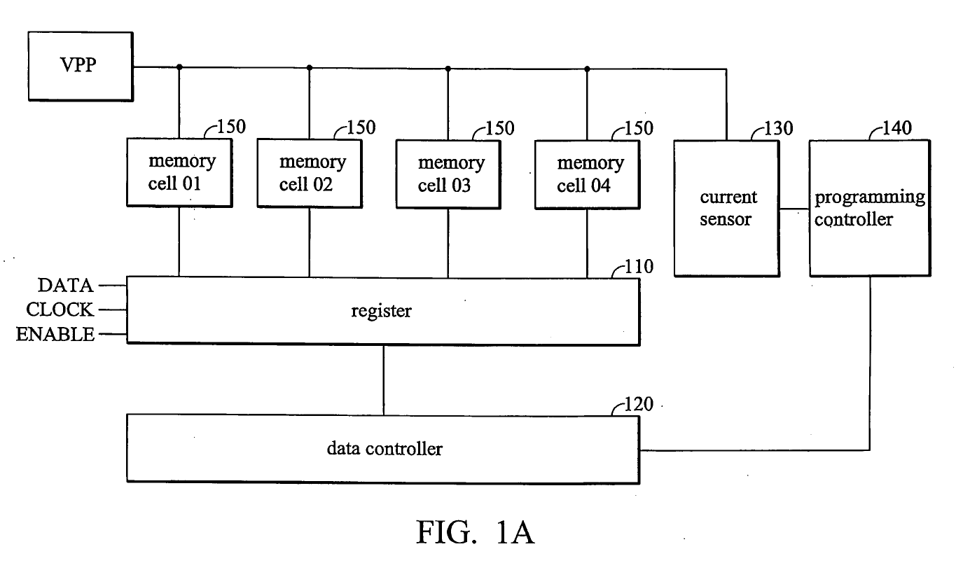

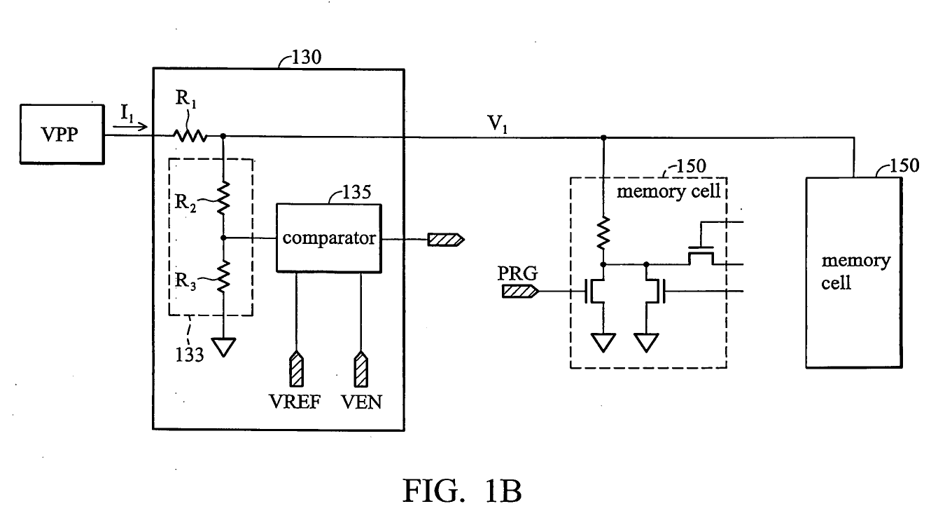

Detection apparatuses for sequentially programming a memory are provided. In an exemplary embodiment of a detection apparatus for sequentially programming a memory in FIG. 1A, a detection apparatus comprises a register 110, a data controller 120, a current sensor 130, and a programming controller 140. The current sensor 130 is coupled to a programming source and a memory cell 150. The current sensor 130 detects change of a programming current between the programming source and the memory cells 150 and generates a control signal according the detected result. In a preferred embodiment, the memory cell 150 is implemented by a fuse memory cell, and the programming source is implemented by a programming pad (VPP). The programming controller 140 is coupled to the current sensor 130. The programming controller 140 receives the control signal and generates a programming state signal. The data controller 120 is coupled to the programming controller 140. The data controller 120 receives the programming status signal to control whether a programming procedure for the next memory cell is performed or not. The register 110 is coupled between the data controller 120 and the memory cells 150. In a preferred embodiment, the register 110 is implemented by a level shift register, which receives data in series or parallel. During the procedure for sequentially programming the memory, some idle resources (such as data transmission lines) can be used for other works, thus enhancing efficiency of the memory.

In FIG. 1A, data is input to the register 110 in series or parallel and stored therein. When the register 110 writes first data into the memory cell 150, the programming source (or programming pad VPP) provides a large amount of current to program the memory cell 250. When the current sensor 130 detects current change, the current sensor 130 generates a control signal to the programming controller 140, and the programming controller 140 then generates a programming state signal to the data controller 120 to perform a programming procedure for the next memory cell 150. The programming procedure is repeated until all the memory cells are programmed.

FIG. 1B shows the current sensor in FIG. 1A. The current sensor 130 comprises a resistor R₁, a comparator 135, and a voltage divider 133 coupled between the resistor R₁ and the comparator 135. The resistor R₁ is disposed on the path of the programming current. When the memory cell 150 is programmed, the programming source (or programming pad VPP) provides a large amount of current I₁. A voltage drop is generated in the resistor R₁ when the current I₁ flows through the resistor R₁, and a voltage V₁ is thus generated. The voltage V₁ is divided by the voltage divider 133 composed by resistors R₂ and R₃. The comparator 135 compares the divided voltage and a reference voltage VREF and generates a control signal to the programming controller 140 according to the comparison result.

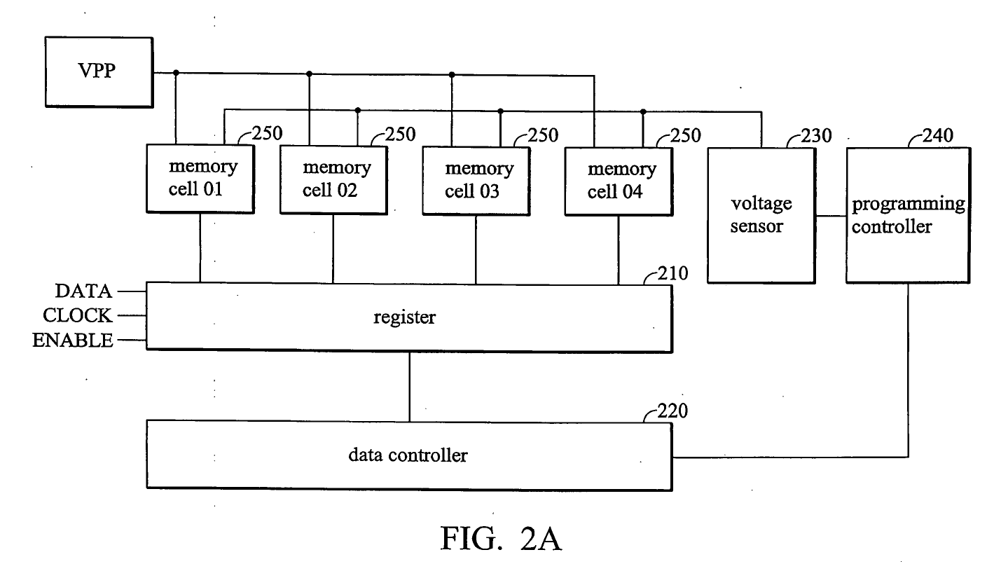

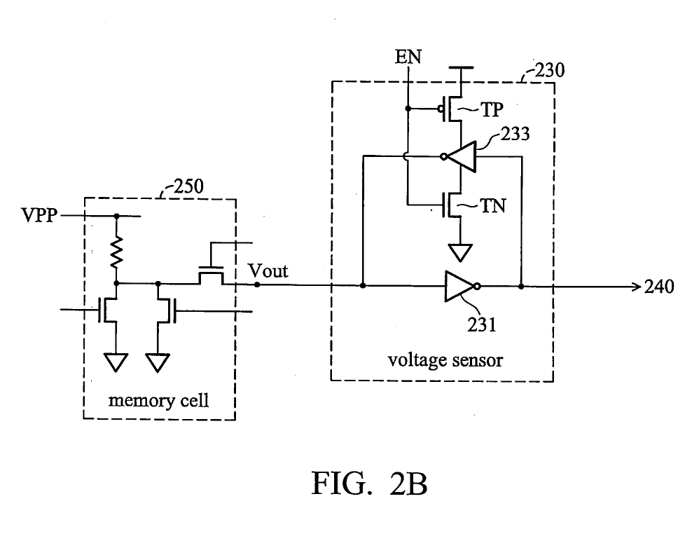

FIG. 2A shows another exemplary embodiment of a detection apparatus for sequentially programming a memory. The detection apparatus comprises a register 210, a data controller 220, a voltage sensor 20, and a programming controller 240. The voltage sensor 230 is coupled to a programming source through a memory cell 250. The voltage sensor 230 detects an output voltage of the memory cell 250 and generates a control signal according the detected output voltage. In a preferred embodiment, the memory cell 250 is implemented by a fuse memory cells, and the programming source is implemented by a programming pad (VPP). The programming controller 240 is coupled to the voltage sensor 230. The programming controller 240 receives the control signal and generates a programming state signal. The data controller 220 is coupled to the programming controller 240. The data controller 220 receives the programming status signal to control whether a programming procedure for a next memory cell is performed or not. The register 210 is coupled between the data controller 220 and the memory cells 250. In a preferred embodiment, the register 210 is implemented by a level shift register, which receives data in series or parallel. During the procedure for sequentially programming the memory, some idle resources (such as data transmission lines) can be used for other works, thus enhancing efficiency of the memory.

In FIG. 2A, data is input to the register 210 in series or parallel and stored therein. When the register 210 writes first data into the memory cell 250, the programming source (or programming pad VPP) provides a large amount of current to program the memory cell 250. When programming the memory cell 250 is successful, the memory cell 250 generates an output voltage to the voltage sensor 230, and the voltage sensor 230 generates a control signal to the programming controller 140 according to the detected voltage change. The programming controller 240 then generates a programming state signal to the data controller 220 to perform a programming procedure for the next memory cell 250. The programming procedure is repeated until all the memory cells are programmed.

FIG. 2B shows the voltage sensor in FIG. 2A. The voltage sensor 230 comprises a first inverter 231, a second inverter 233, a P-type MOS (PMOS) transistor TP, and an N-type MOS (NMOS) transistor TN. The second inverter 233 is coupled to the first inverter in inverse and in parallel. Referring to FIG. 2B, an input terminal and an output terminal of the first inverter 231 are respectively coupled to an output terminal and an input terminal of the second inverter 233. The input terminal of the first inverter 231 receives an output voltage Vout of the memory cell 250, and the output terminal thereof is coupled to the programming controller 240. The second inverter 233 is coupled to a first fixed potential and a second fixed potential respectively through the PMOS transistor TP and the NMOS transistor TN. In a preferred embodiment, the first fixed potential is provide by a voltage supply source, and the second fixed potential is provided by a ground terminal. The PMOS transistor TP and the NMOS transistor TN are controlled by a detection enable signal EN.

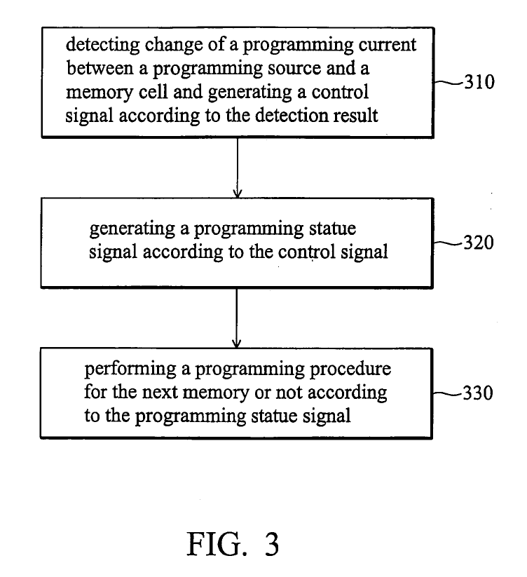

FIG. 3 is a flow chart of an exemplary embodiment of a detection method for sequentially programming a memory. The detection method comprises detecting change of a programming current between a programming source and a memory cell, generating a control signal according to the detection result (step 310), and generating a programming state signal according to the control signal (step 320). In a preferred embodiment, the detection method further comprises performing a programming procedure for the next memory or not according to the programming state signal (step 330).

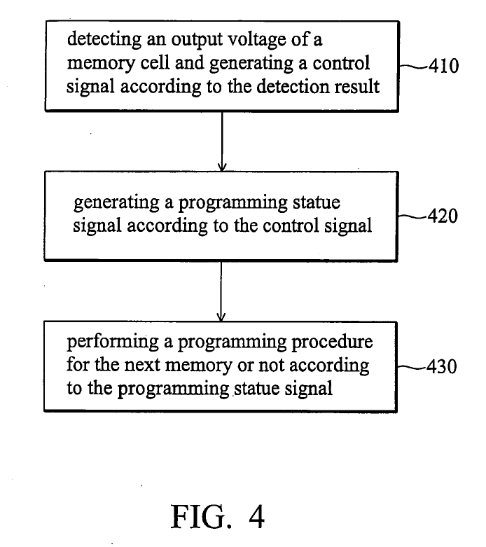

FIG. 4 is a flow chart of another exemplary embodiment of a detection method for sequentially programming a memory. The detection method comprises detecting an output voltage of a memory cell, generating a control signal according to the detection result (step 410), and generating a programming state signal according to the control signal (step 420). In a preferred embodiment, the detection method further comprises performing a programming procedure for the next memory or not according to the programming state signal (step 430).

According to the detection apparatus for sequentially programming a memory, a current sensor or voltage sensor is used to detect a programming state of a memory cell and determine whether a programming procedure for the next memory is performed. In this sequential programming mode, only one programming pad is required. Compared with a conventional memory with a plurality of programming pads, the memory programmed sequentially according to the invention saves area and costs. Moreover, during the procedure for sequentially programming memory, some idle resources (such as data transmission lines) can be used for other works, thus enhancing efficiency of the memory.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A detection apparatus for sequentially programming a memory, comprising:
a current sensor, coupled to a programming source and a memory cell, for detecting change of a programming current between the programming source and the memory cell and generating a control signal according to the detection result;
a programming controller, coupled to the current sensor, for receiving the control signal and generating a programming state signal.

2. The detection apparatus as claimed in claim 1 further comprising a data controller, coupled to the programming controller, for receiving the programming state signal to control whether a next memory cell is programmed or not.

3. The detection apparatus as claimed in claim 2 further comprising a register coupled to the data controller and the memory cells.

4. The detection apparatus as claimed in claim 3, wherein the register is implemented by a level shift register and receives data in series or in parallel.

5. The detection apparatus as claimed in claim 1, wherein the memory cell is implemented by a fuse memory cell.

6. The detection apparatus as claimed in claim 1, wherein the current sensor comprises a resistor, a comparator, and a voltage divider coupled between the resistor and the comparator, and resistor is disposed on a path of the programming current.

7. A detection apparatus for sequentially programming a memory, comprising:
a voltage sensor, coupled to a programming source through a memory cell, for detecting an output voltage of the memory cell and generating a control signal according to the detection result;
a programming controller, coupled to the voltage sensor, for receiving the control signal and generating a programming state signal.

8. The detection apparatus as claimed in claim 7 further comprising a data controller, coupled to the programming controller, for receiving the programming state signal to control whether a next memory cell is programmed or not.

9. The detection apparatus as claimed in claim 8 further comprising a register coupled to the data controller and the memory cells.

10. The detection apparatus as claimed in claim 9, wherein the register is implemented by a level shift register and receives data in series or in parallel.

11. The detection apparatus as claimed in claim 7, wherein the memory cell is implemented by a fuse memory cell.

12. The detection apparatus as claimed in claim 7, wherein the voltage sensor comprises:
a first inverter having an input terminal receiving the output voltage of the memory cell and an output terminal coupled to the programming controller;
a second inverter coupled to the first inverter in inverse and in parallel;
a P-type MOS (PMOS) transistor; and
an N-type MOS (NMOS) transistor, wherein the second inverter is coupled to a first fixed potential and a second fixed potential respectively through the PMOS transistor and the NMOS transistor, and the PMOS transistor and the NMOS transistor are controlled by a detection enable signal.

13. The detection apparatus as claimed in claim 12, wherein the second fixed potential is provided by a ground terminal.

14. A detection method for sequentially programming a memory comprising:
detecting change of a programming current between a programming source and a memory cell and generating a control signal according to the detection signal; and
generating a programming state signal according to the control signal.

15. The detection method as claimed in claim 14 further comprising programming the next memory or not according to the programming state signal.

16. The detection apparatus as claimed in claim 14, wherein the memory cell is implemented by a fuse memory cell.

17. A detection method for sequentially programming memory comprising:
detecting an output voltage of a memory cell and generating a control signal according to the detection signal; and
generating a programming state signal according to the control signal.

18. The detection method as claimed in claim 17 further comprising programming the next memory or not according to the programming state signal.

19. The detection method as claimed in claim 17, wherein the memory cell is implemented by a fuse memory cell.
